(19) United States
(12) Patent Application Publication
(10) Pub. No.: US 2009/0280588 A1
(43) Pub. Date: Nov. 12, 2009

(54) METHOD OF FORMING AN ELECTRONIC DEVICE INCLUDING REMOVING A DIFFERENTIAL ETCH LAYER

(76) Inventors: Leo Mathew, Austin, TX (US); Dharmesh Jawarani, Round Rock, TX (US)

Correspondence Address: LARSON NEWMAN & ABEL, LLP, 5914 WEST COURTYARD DRIVE, SUITE 200, AUSTIN, TX, 78730, US

(21) Appl. No.: 12/435,947

(22) Filed: May 5, 2009

Related U.S. Application Data
(60) Provisional application No. 61/050,709, filed on May 6, 2008.

(51) Int. Cl. H01L 21/3205; H01L 31/02; H01L 33/00; H01L 21/20

(52) U.S. Cl. 438/22; 438/685; 438/686; 438/687; 438/597; 438/98; 438/478; 438/604; 438/606; 438/680; 257/E21.295; 257/E31.11; 257/E33.066; 257/E21.09

(57) ABSTRACT

A method of forming an electronic device can include forming a metallic layer over a side of a workpiece including a substrate, a differential etch layer, and a semiconductor layer. The differential etch layer may lie between the substrate and the semiconductor layer, and the semiconductor layer may lie along the side of the workpiece. The process can further include selectively removing at least a majority of the differential etch layer from between the substrate and the semiconductor layer, and separating the semiconductor layer and the metallic layer from the substrate. The selective removal can be performed using a wet etching, dry etching, or electrochemical technique. In a particular embodiment, the same plating bath may be used for plating the metallic layer and selectively removing the differential etch layer.

### RELATED APPLICATION

This is related to and claims priority under 35 U.S.C. §119(e) to U.S. Patent Application No. 61/050,709 entitled “Method of Forming Devices on a Semiconductor Layer and Using Wet Process and Related Devices” by Mathew et al. on May 6, 2008, which is assigned to the current assignee hereof and incorporated herein by reference in its entirety.

### FIELD OF THE DISCLOSURE

The present invention relates generally to electronic devices, and in particular to methods for making electronic devices on a layer that has been separated from a substrate.

### RELATED ART

The use of semiconductor layers that have been transferred onto substrates or substrates that have been thickened using various growth processes have been used in technologies such as silicon-on-insulator (SOI) technology. The transfer of layers therein involves process incorporation of a cleaving plane, sticking to a foreign substrate and separation of the surface layer. The incorporation of a cleaving plane is performed using a process of ion implantation or formation of porous layers. The bonding to a foreign substrate involves Van der Waals forces on extremely smooth surfaces; eutectic bonding using suitable materials; or thermo-compression bonding using suitable materials, elevated temperature, and elevated pressure. The separation involves annealing of the bubbles and cracks formed during ion implantation. In the formation of devices, the cycle time and cost of processes such as ion implantation and the formation of smooth surfaces is expensive.

### BRIEF DESCRIPTION OF THE DRAWINGS

Embodiments are illustrated by way of example and are not limited in the accompanying figures.

FIG. 1 includes an illustration of a cross-sectional view of a portion of a workpiece comprising a substrate, a differential etch layer, and a semiconductor layer.

FIG. 2 includes an illustration of a cross-sectional view of the workpiece of FIG. 1 after formation of a conductive layer.

FIG. 3 includes an illustration of a cross-sectional view of the workpiece of FIG. 2 after the removal of part of the differential etch layer.

FIG. 4 includes an illustration of a cross-sectional view during selective removal of the differential etch layer using a wet etching technique.

FIG. 5 includes an illustration of a cross-sectional view during selective removal of the differential etch layer using an electrochemical technique.

FIG. 6 includes an illustration of a cross-sectional view of the workpiece of FIG. 4 or 5 after separating the semiconductor layer from the substrate.

FIG. 7 includes an illustration of a cross-sectional view of a substantially completed semiconductor device.

FIG. 8 includes an illustration of a cross-sectional view of an embodiment where semiconductor layers have been separated from opposite sides using any of procedures described with respect to FIG. 1 through FIG. 7.

FIG. 9 includes an illustration of a cross-sectional view of t a portion of a workpiece comprising a substrate, in ingot form, a doped region, and a conductive layer.

FIG. 10 includes an illustration of a cross-sectional view of the workpiece of FIG. 9 after a combination of a semiconductor layer, the doped region, the conductive layer has been separated from the substrate.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other teachings can certainly be utilized in this application.

Before addressing details of embodiments described below, some terms are defined or clarified. Group numbers corresponding to columns within the Periodic Table of the elements use the “New Notation” convention as seen in the CRC Handbook of Chemistry and Physics, 81^{st} Edition (2000-2001).

The term “metal” and any of its variants are intended to refer to a material that includes an element that is (1) within any of Groups 1 to 12, or (2) within Groups 13 to 15, an element that is along and below a line defined by atomic numbers 13 (Al), 50 (Sn), and 83 (Bi), or any combination thereof. Metal does not include silicon or germanium. Note, however, that a metal silicide is a metallic material.

The term “semiconductor element” is intended to mean an element by itself or in combination with one or more elements that form a semiconductor. For Group 14 semiconductors, semiconductor elements include Si, Ge, and C, but do not include Group 13 or Group 15 elements. Such Group 13 or Group 15 elements within a Group 14 semiconductor would be dopants that affect the conductivity and other electronic characteristics of the Group 14 semiconductor. For Group 13-Group 15 (III-V) semiconductors, semiconductor elements include Group 13 and Group 15 elements, but do not include Group 14 elements.

As used herein, the terms “comprises,” “comprising,” “includes,” “including,” “has,” “having” or any other variation thereof, are intended to cover a non-exclusive inclusion. For example, a method, article, or apparatus that comprises a list of features is not necessarily limited only to those features but may include other features not expressly listed or inherent to such method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” is employed to describe elements and components described herein. This is done merely for convenience and to give a general sense of the scope of the invention. This description should be read to include one or at least one and the singular also includes the plural, or vice versa, unless it is clear that it is meant otherwise. For example, when a single item is described herein, more than one item may be used in place of a single item. Similarly, where more than one item is described herein, a single item may be substituted for that more than one item.

In addition, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the semiconductor and electronic arts.

A method of forming an electronic device can include forming a metallic layer over a side of a workpiece including a substrate, a differential etch layer, and a semiconductor layer.

The differential etch layer may lie between the substrate and the semiconductor layer, and the semiconductor layer may lie along the side of the workpiece. The process can further include selectively removing at least a majority of the differential etch layer from between the substrate and the semiconductor layer, and separating the semiconductor layer and the metallic layer from the substrate. The selective removal can be performed using a wet etching, dry etching, or electrochemical technique. In a particular embodiment, the same bath may be used for plating the metallic layer and selectively removing the differential etch layer. In another embodiment, a combination of chemical etch and electrochemical processes can be used to selectively remove the differential etch layer, as will be described later in this specification. This and other embodiments of the present invention will be better understood by reference to the drawings and the claims.

In embodiments described herein, the thickness of the semiconductor layer can be made more reproducibly as compared to other techniques. Although the description below provides many details, including particular numerical values and configurations, after reading this specification, skilled artisans will appreciate that the embodiments described herein merely illustrate and do not limit the scope of the present invention.

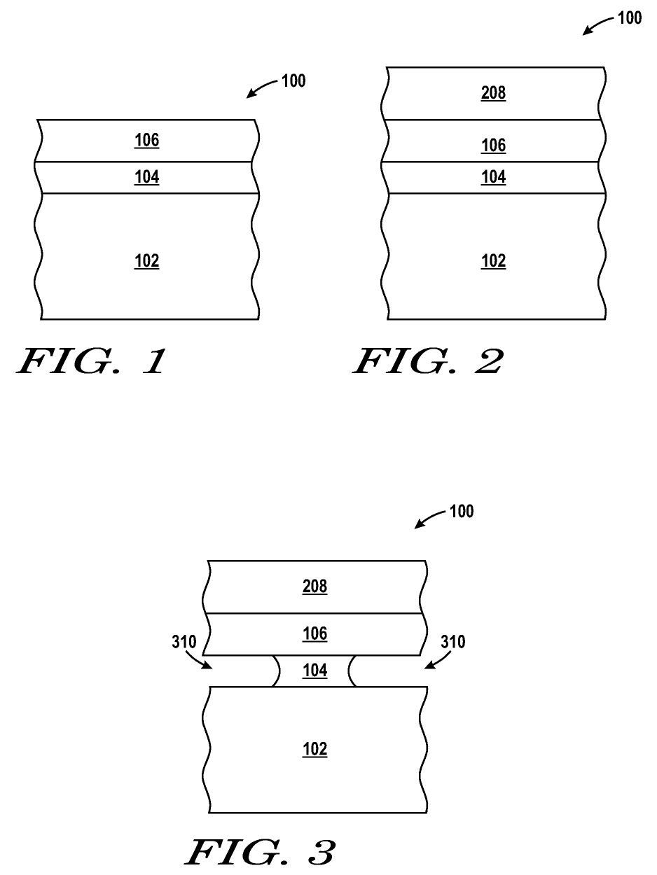

FIG. 1 illustrates a workpiece 100 comprising a substrate 102, a differential etch layer 104, and a semiconductor layer 106. The substrate 102 can be rigid or flexible, yet still have a sufficient thickness to provide proper mechanical support for the differential etch layer 104 and the semiconductor layer 106.

The substrate 102 may be a semiconductor substrate comprising a Group 14 element (silicon, germanium, or carbon), any combination of Group 14 elements (silicon germanium, carbon-doped silicon, or the like), or Group 13-Group 15 semiconductors (gallium arsenide, gallium nitride, indium phosphide, gallium indium arsenide, or the like). The substrate 102 can include a substantially monocrystalline, amorphous, or polycrystalline semiconductor substrate. In another embodiment, the substrate 102 can include a glass, polymer, metal, or ceramic material, or any combination thereof. In other embodiments, various combinations of materials may form the substrate 102.

The differential etch layer 104 will be subsequently removed selectively to the substrate 102 and the semiconductor layer 106. Thus, the differential etch layer 104 has a composition different from each of the substrate 102 and semiconductor layer 106. Therefore, a wide variety of materials may be used for the differential etch layer 104. An exemplary, non-limiting material includes an oxide, a nitride, an oxynitride, a metallic element or compound, a semiconductor material, or the like. In a particular embodiment, the differential etch layer 104 may be substantially lattice matched to the substrate 102, the semiconductor layer 106, or both.

In particular, the substrate 102 and the semiconductor layer 106 can include the same semiconductor material or different semiconductor materials, and the differential etch layer 104 can include a metal oxide or an oxide of a different semiconductor element. In another embodiment, the substrate 102 and the semiconductor layer 106 includes silicon, and the differential etch layer 104 includes germanium. In a particular embodiment, silicon is the principal material of the substrate 102 and semiconductor layer 106, and germanium (substantially free of another Group 14 element) or silicon germanium is the principal material of the differential etch layer 104. In a more particular embodiment, within the different etch layer 104, the germanium content within the silicon germanium material is at least approximately 0.01 atomic % of the total element semiconductor content or is at least approximately 10 atomic % of the total semiconductor element content, and in another more particular embodiment, the germanium content within the silicon germanium material is no greater than approximately 99 atomic % of the total semiconductor element content or is no greater than approximately 90 atomic % of the total semiconductor element content. In still another embodiment, one or more Group 14 elements are the principal material of the substrate 102 and semiconductor layer 106; a spinel material is the principal material of the differential etch layer 104; and the substrate 102, differential etch layer 104, and semiconductor layer 106 have the same crystal orientation (e.g., surfaces of each along the interfaces are oriented along a (100) crystal plane).

In still another embodiment, the differential etch layer 104 can include a porous material. The differential etch layer 104 may be a porous material as formed or may be converted to a porous material. For example, a patterned masking layer (not illustrated) may be formed over the substrate 102. The patterned masking layer can include an oxide, a nitride, an oxynitride, or a combination thereof. Portions of the substrate 102 may be exposed at openings extending through the patterned masking layer. The differential etch layer 104 may be selectively grown or deposited from the exposed portions of the substrate 102. The patterned masking layer can then be etched. Thus, the substrate 102 may include a substantially monocrystalline semiconductor material, and the differential etch layer 104 can include a porous semiconductor material of the same or different composition. In a further embodiment, the differential etch layer 104 can be formed by converting a surface region of the substrate 102 into a porous material. In this particular embodiment, an etching compound can be used that preferentially etch the substrate 102 along one or more particular crystal planes.

In yet another embodiment, a substrate 102 can include an n-type or lightly p-type doped semiconductor material, and the differential etch layer 104 can include a heavily p-type doped semiconductor material. An etching compound can be used to preferentially etch the heavily p-type doped semiconductor material along one or more particular crystal planes. Alternatively, an electrochemical process can be used to anodize the heavily p-type doped semiconductor material. Thus, different processes can be used to form the differential etch layer 104 as a porous layer. After reading this specification, skilled artisans will appreciate that other combinations of materials and concentrations can be used without departing from the scope of the present invention.

The differential etch layer 104 should be sufficiently thick that removal of the layer is not limited to a diffusion rate of an etching or another removal species. Although there is no theoretical upper limit on the thickness, manufacturing costs, time, or both may increase as the differential etch layer becomes too thick. In an embodiment, the differential etch layer 104 can have a thickness of at least approximately 1 nm or at least approximately 20 nm, and in another embodiment, the differential etch layer 104 may be no greater than approximately 200 nm or no greater than approximately 200 nm.

The semiconductor layer 106 can include a single semiconductor material or a combination of semiconductor materials, such as those previously described with respect to a semiconductor substrate for the substrate 102. The thickness of the semiconductor layer 106 can depend on the semiconductor device being formed (e.g., a photovoltaic cell, a light emitting device, a radiation detector, or the like) and the semiconductor element or elements within the semiconductor layer 106. In an embodiment, the semiconductor layer 106 has thickness of at least approximately 0.1 micron or is at least approximately 1 micron, and in another more particular embodiment, the semiconductor layer 106 has thickness no greater than approximately 10 microns or is no greater than approximately 100 microns.

Although not illustrated, an optional doped region may be formed within the semiconductor layer 106, over the semiconductor layer 106, or both. The doped region may includes a dopant of the opposite conductivity type as compared to the semiconductor layer 106, so that a pn junction is formed. The doped region can include an n-type or a p-type dopant. The doped region can be formed by gas-phase furnace doping, a spin-on dopant, depositing or growing a doped layer (a doped glass, a doped semiconductor layer (amorphous, polycrystalline, substantially monocrystalline), or by implantation. An anneal or dopant drive may be performed if needed or desired. In an embodiment, the peak concentration of the doped region is at least approximately 10¹⁷, 10¹⁸, or 10¹⁹ atoms/cm³. In an embodiment, the junction depth of the doped region is at least approximately 0.01 micron or at least approximately 0.1 micron, and in another embodiment, the junction depth of the doped region is no greater than approximately 5 microns or no greater than approximately 1 micron. In other embodiments, the doped region can have other dopant concentrations or junction depths than previously described. If the dopant source for the doped region includes a layer formed over the semiconductor layer 106, the layer may or may not be removed after the doped region is formed. For example, a doped silicon layer may be formed over the semiconductor layer 106 and remain. In this particular embodiment, the doped region may principally lie within the doped silicon layer.

A conductive layer 208 is formed over the semiconductor layer 106 as illustrated in FIG. 2. The conductive layer 208 can include a metallic layer and have one or more films therein. For example, the metallic layer can include an adhesion film, a barrier film, a seed film, another suitable film, or any combination thereof. The adhesion film can include a refractory metal (titanium, tantalum, tungsten, or the like), and the barrier film can include a metal nitride (TiN, TaN, WN of the like) or a metal semiconductor nitride (TaSiN, WSiN, or the like). The seed film can include a transition metal or transition metal alloy, and in a particular embodiment, the seed film can include titanium, nickel, palladium, tungsten, copper, silver, or gold. In other embodiments, other materials may be used within the adhesion film, barrier film, seed film, or any combination thereof. The metal-containing film can be formed by physical vapor deposition (PVD, such as evaporation or sputtering), chemical vapor deposition (CVD), atomic layer deposition (ALD), electrochemistry, a spin-on technique, a metallic paste deposition, another suitable method, or any combination thereof. In another embodiment, the metal-containing film may be bonded to the semiconductor layer 106 by forming a metal film over the workpiece 100 and reacting the metal film to form a metal silicide. The metal-containing film may be at least approximately 1 nm or at least approximately 10 nm, and in another embodiment, the metal-containing film is no greater than approximately 0.1 micron or no greater than approximately 10 microns.

The conductive layer 208 can further include a conductive film formed over the metal-containing film. In a particular embodiment, the conductive layer 208 or the conductive film, either by itself, may have a thickness, such that it provides sufficient mechanical support to the semiconductor layer 106 after the differential etch layer 104 is removed. Thus, each of the conductive layer 208 and its conductive film is substantially thicker than the semiconductor layer 106. The conductive film may be substantially thicker and have a relatively higher conductance as compared to the metal-containing film. In a particular embodiment, the conductive film is at least approximately 11 times, approximately 50 times, or approximately 500 times thicker than the metal-containing film.

The conductive film can include any of the metals or metal alloys previously described with respect to the metal-containing film. In a particular embodiment, the conductive film comprises tin, nickel, chromium, copper, silver, gold, or a combination thereof. Similar to the metal-containing film, the conductive film can include a single film or a plurality of films. In a particular embodiment, the conductive film can consist essentially of gold, and in another embodiment, the conductive film can be mostly copper with a relatively thin indium-tin alloy to help improve soldering during a subsequent bonding operation. Other combinations of materials can be used such that the composition of the conductive film is tailored to a particular application. The conductive film can be formed by PVD, CVD, ALD, electrochemistry, a spin-on technique, a metallic paste deposition (i.e., mechanically applying a metallic paste over the semiconductor layer 106), another suitable method, or any combination thereof. The conductive film and the metal-containing film can include the same composition or different compositions and be formed using the same technique or different techniques. In an embodiment, the conductive film is at least approximately 10 microns or at least approximately 30 microns, and in another embodiment, the conductive film is no greater than approximately 2 mm or no greater than approximately 100 mm. In still another embodiment, the metal-containing layer may be omitted, and the conductive layer 208 may consist essentially of the conductive film.

The differential etch layer 104 is selectively removed, as illustrated in FIG. 3. As the differential etch layer 104 is selectively removed, a gap 310 is formed between the substrate 102 and 106. The selective removal can be performed as an isotropic process.

FIG. 4 includes an illustration of wet etch apparatus 400 that can be used to selectively remove the different etch layer 104 using a wet etching technique. The workpieces may be oriented horizontally (as illustrated in FIG. 4) or vertically (not illustrated). In the embodiment as illustrated in FIG. 4, the apparatus 400 includes a container 410 in which an etching solution 412 dynamically moves, as illustrated by arrows 416. The dynamic movement can occur using a stir bar 414, paddles, a circulating pump, ultrasonic or megasonic agitation, other suitable mechanical agitation, or any combination thereof. In another embodiment, a static bath can be used. Because the differential etch layer 104 is removed selectively, the etchant used for the solution 412 will etch the differential etching layer 104 significantly faster than the substrate 102, semiconductor layer 106, and the conductive layer 208. The etchant can include hydrogen peroxide, hydrofluoric acid, water, sulfuric acid, another suitable etchant, or any combination thereof. In another embodiment, a dry etch process can be used. The dry etch can be performed with or without a plasma. If a plasma is used, downstream etching system can be used to help make the etch process more isotropic, than if a reactive-ion etching technique would be used.

The wet and dry etching techniques may be performed on a single workpiece at a time or as a batch processing system. In a particular embodiment, the apparatus 400 can be configured to process a plurality of workpieces at the same time. For example, the apparatus 400 may receive a cassette (not illustrated) of 25, 50, or another number of workpieces. Similarly, a dry etch apparatus may be configured to process one or more than one workpiece at a time. For a dry etch apparatus, a quartz boat may be used. With dry etching, 100 workpieces, and potentially more, can be processed in the same batch. Thus, a plurality of workpieces can be processed substantially simultaneously during at least a period of time. Therefore, total processing time on a per-workpiece basis can be substantially reduced.

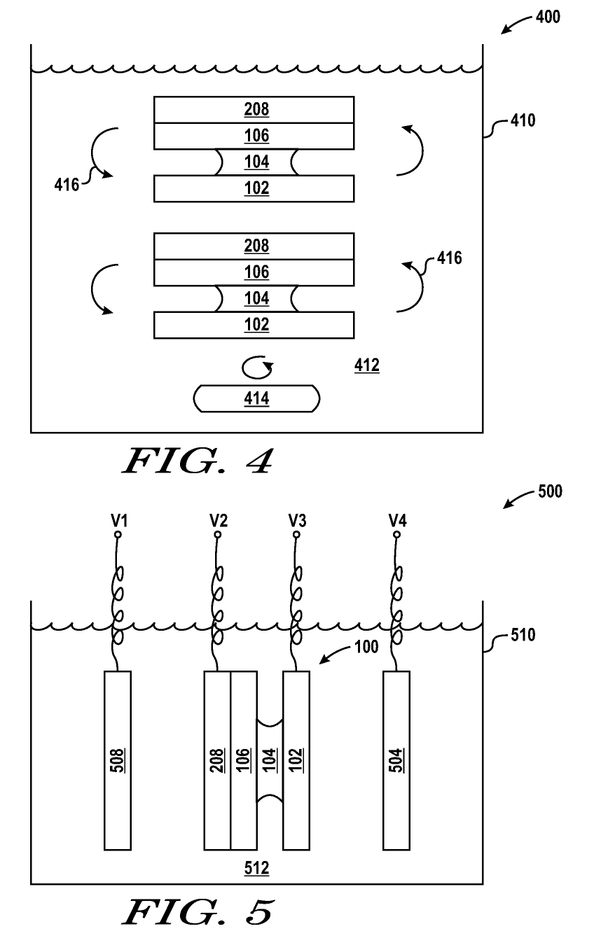

FIG. 5 includes an illustration of electrochemical apparatus 500 that can be used to selectively remove the different etch layer 104. In a particular embodiment, the electrochemical apparatus can be used to plate a material onto the workpiece 100, de-plate a material from the workpiece 100, or both. The apparatus 510 can include a container 510 that includes an ionic solution 512. Electrodes 504 and 508 are submerged within the apparatus. In an embodiment, either or both electrodes 504 and 508 may be partially or completely submerged within the ionic solution 512. The electrode 504 can include an elemental metal or metallic alloy. In a particular embodiment, the electrode 504 can include iron, nickel, chromium, tin, copper, silver, gold, another suitable conductive material, or any combination thereof. The electrode 508 can be a source for material to be deposited as the conductive film within the conductive layer 208, and therefore, the electrode 508 can include a material previously described with respect to films within the conductive layer 208, and particularly, the conductive film.

Each of the electrodes 504 and 508, the conductive layer 208 (e.g., a seed film), and the substrate 100 can be connected to different voltage terminals. Table 1 includes the relative voltages for terminals when plating and selectively removing in accordance with a particular embodiment. The voltages are represented as V₁, V₂, V₃, and V₄ within FIG. 5. Note that although pluses and minuses are used in the table to illustrate relatively higher and lower voltages; the absolute voltages may both be positive (e.g., +2 V and +5 V), negative (e.g., −2 V and −5 V), a combination of positive and negative (e.g., −1 V and +1 V), or a combination of ground (or 0 V) and a negative or positive voltage. Further, float is used to designate that a terminal electrically floats, or the terminal is within a highly resistivity circuit (i.e., substantially no or an insignificant amount of current flows through a terminal denoted as floating).

TABLE 1

Action

| | V₁ | V₂ | V₃ | V₄ |
|---|---|---|---|---|
| Plate conductive layer 208 | − | + | Float | Float |
| Selectively remove layer 104 | Float | Float | − | + |

With the configuration as illustrated in FIG. 5, the formation of the conductive film within the conductive layer 208, as previously described, and the selective removal of the differential etch layer 104 may be performed within the same apparatus 500. Thus, the composition of the electrode 508 can include a material is plated onto the workpiece 100 as part of the conductive layer 208. Material selectively removed from the differential etch layer 104 is plated onto the electrode 504. To reduce the likelihood that material from the electrode 508 is plated onto the substrate 102 and the electrode 504 when forming the conductive film for the conductive layer 208, the terminals for the substrate 104 and the electrode 504 are allowed to float (i.e., V₃ and V₄ in a float state). Conversely, to reduce the likelihood that material from the differential etch layer 104 is plated onto the conductive layer 208 and the electrode 508 when selectively removing (i.e., de-plating) the differential etch layer 104, the terminals for the conductive layer 208 and the electrode 508 are allowed to float (i.e., V₁ and V₂ in a float state).

In another embodiment, a combination of chemical etch and electrochemical processes may be used. For example, the differential etch layer 104 may be anodized to selectively remove at least part of the differential etch layer. For example, the anodization may selectively remove germanium from the differential etch layer 104. When the differential etch layer 104 includes silicon germanium, the silicon may remain as a porous layer. A subsequent wet etch can remove the porous silicon relatively quickly. Alternatively, anodization can be used to improve the selectively of a wet etching process. For example, the differential etch layer 104 may include a heavily p-type doped semiconductor material. The anodization can remove the p-type semiconductor material as compared to n-type or lightly doped p-type semiconductor material. In a particular embodiment, the substrate 102 and the semiconductor layer 106 may include n-type or lightly doped p-type silicon, and the differential etch layer 104 can include heavily p-type doped silicon germanium. Thus, a hybrid anodization-wet etch process can allow the differential etch layer 104 to be removed selectively to the substrate 102 and the semiconductor layer 106.

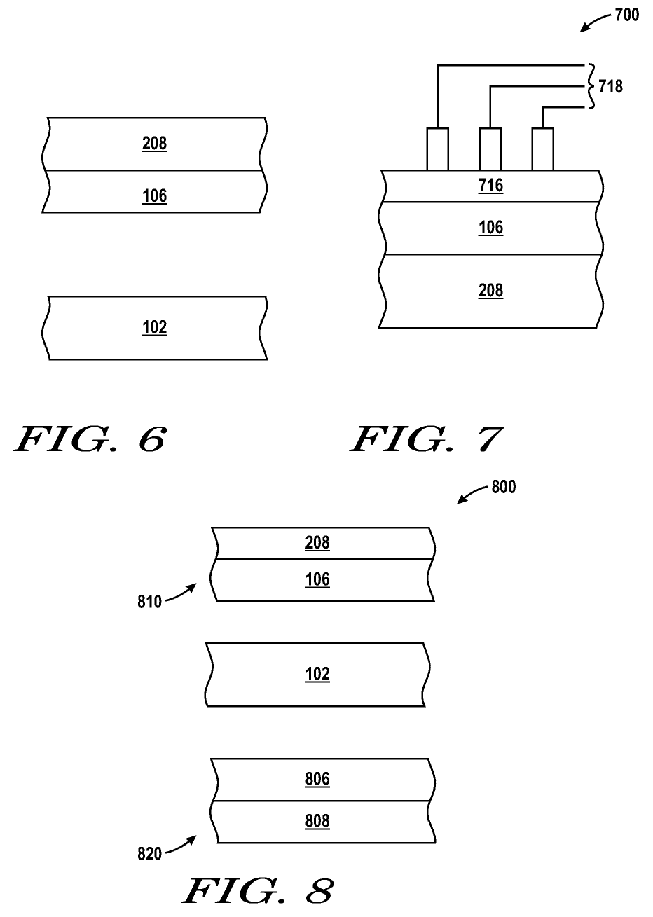

FIG. 6 includes an illustration of a cross-sectional view after substantially all of the differential etch layer has been removed. In the embodiment as illustrated in FIG. 6, the combination of the semiconductor layer 106 and the conductive layer 208 has been separated from the substrate 102. The substrate 102 can be reused as a handle substrate. The combination of the semiconductor layer 106 and conductive layer 208 can be further processed. A doped region, similar to that previously described with respect to the semiconductor layer 106, may be formed along the exposed surface of the semiconductor layer 106 in addition to or instead of the doped region that was or would have been formed along the opposite side of the semiconductor layer 106. In an alternative embodiment, no separate doped region may be used.

In another embodiment (not illustrated), the selective removal may be performed such that a majority, but not all, of the differential etch layer 104 is selectively removed. A mechanical separation operation may be used to complete the separation of the combination the semiconductor layer 106 and the conductive layer 208 from the substrate 102. For In a particular embodiment, the separation may occur by cleaving or fracturing the substrate 102 at a location at or near where the separation is to be performed. A wedge, wire, or saw may be used to aid in the mechanical separation. In another embodiment, a metallic paste can be mechanically applied over the workpiece, and a stiffened or handling substrate can be attached to the metallic paste and used to aid the separation operation.

FIG. 7 illustrates a semiconductor device 700 after forming an intervening layer 716 and a patterned interconnect layer 718. The intervening layer 716 can be used as a passivation or antireflective coating. The intervening layer 716 may include an oxide, a nitride, an epitaxial layer or a non-epitaxial layer, or any combination thereof. The intervening layer 716 can be patterned to define openings (not illustrated) through which the interconnect layer 718 may have electrical connection to the semiconductor layer 106 or a doped region therein or thereof. The interconnect layer 718 can be formed using a conventional or proprietary technique. In a particular embodiment, the semiconductor device 700 can be used as one or more photovoltaic cells, light emitting diodes, or radiation sensors. In another embodiment, the semiconductor device 700 may be further processed and singulated to form light emitting devices.

An electronic device can include the semiconductor device 700 or a plurality of semiconductor devices similar to or different from the semiconductor device 700. The electronic device can be a solar panel that includes one or more of the semiconductor devices, wherein the semiconductor devices are photovoltaic devices. In another embodiment, the electronic device can be a display that includes one or more of the semiconductor devices, wherein the semiconductor devices are light emitting devices. In still another embodiment, the electronic device can be a radiation detector that includes one or more of the semiconductor devices, wherein the semiconductor devices are radiation sensors. The electronic device can include different types of semiconductor devices. For example, an electronic device may include a display that includes control logic to adjust the intensity of the display based on the ambient light level within a room. In this particular electronic device, both light emitting devices and radiation sensors may be used. After reading this specification, skilled artisans will appreciate that many different configurations can be used to achieve a wide variety of applications.

FIG. 8 illustrates a workpiece 800 in another embodiment, wherein the method of separation of the semiconductor layers occurs along opposite sides of the substrate 102. Any of the previously described processes can be used for the method. The embodiment as illustrated in FIG. 8 includes a particular, non-limiting embodiment. After reading this specification, skilled artisans will appreciate that other embodiments may be used without departing from the concepts described herein.

In the embodiment as illustrated in FIG. 8, differential etch layers (not illustrated) and semiconductor layers 106 and 806 are formed along opposite sides of the substrate 102. The differential etch layers and semiconductor layers 106 and 806 can be formed using any of the techniques as previously discussed with respect to the differential etch layer 104 and the semiconductor layer 106 in FIG. 1. The differential etch layers may have the same composition or different compositions, may be formed the same formation technique or different formation techniques, and the may be formed at substantially the same time or at different times. The semiconductor layers 106 and 806 may have the same composition or different compositions, may or may not have a doped region, may be formed the same formation technique or different formation techniques, and the may be formed at substantially the same time or at different times.

The conductive layers 208 and 808 are formed along opposite exposed sides of the workpiece. The metallic layers 208 and 808 can be formed using any the techniques as previously discussed with respect to the conductive layer 208 in FIG. 3. The conductive layers 208 and 808 may have the same films and compositions or different films or different compositions, have the same thickness or different thicknesses, may be formed the same or different formation technique or different formation techniques, and the may be formed at substantially the same time or at different times.

If needed or desired, any of the previously described mechanical operations can be used to assist in separating the semiconductor layer 106, 806, or both layers from the substrate 102. Subsequent processing, such as forming patterned interconnect layers adjacent to the semiconductor layers 106 and 806, may be performed in forming semiconductor devices 810 and 820.

Dual processing embodiments, such as the embodiment previously described and illustrated in FIG. 8, may allow one or more processing operations to be performed simultaneously, and thus, increase equipment throughput. The same type of different types of semiconductor devices may be formed along the opposite sides of the substrate 102.

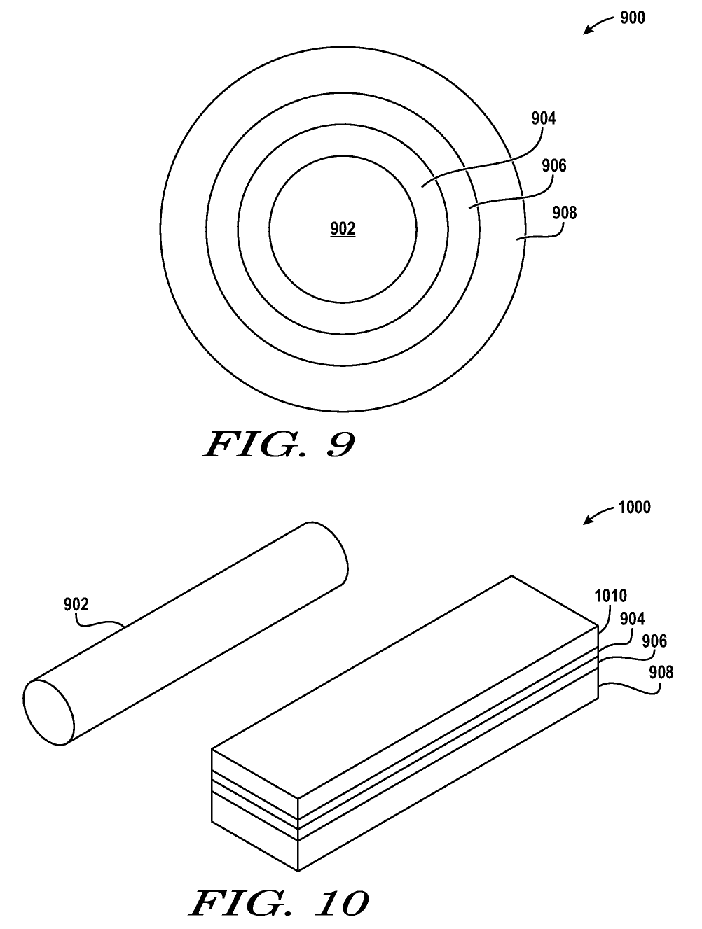

Embodiments previously described may use substrates that are in a wafer form. In another embodiment, the substrate may be in an ingot form. In a particular embodiment as illustrated in FIG. 9, the substrate 902 can be substantially cylindrical. Such a substrate can be made from a boule grown using a Czochralski growth technique and machined to the desired shape. The ingot can have a diameter of approximately 50 mm to approximately 300 mm or even larger. The length of the ingot can be greater than the diameter and can range from approximately 150 mm to approximately 5 meters. The substrate 902 can include any of the materials are previously described with respect to the substrate 102. The workpiece 900 further includes a doped region 904, a metal-containing film 906, and a conductive film 908, which can includes any of the materials, have any of the thicknesses, and be formed using any of the techniques as previously described with respect to the doped region 204, the metal-containing film 206, and the conductive film 308, respectively, as previously described. A separation-enhancing species (not illustrated) can be introduced into the workpiece during an ion implantation operation, during formation of the conductive film 308, or both. After reading this specification, skilled artisans will appreciate that one or more of the regions or films of the workpiece 900 are not required and may not be used, and that other regions or films as previously described but are not illustrated may be used.

The conductive film 908 can be scored, perforated, or cut to provide a weakened location from which separation can more readily start. The workpiece 900 is then annealed using annealing conditions as previously described. During heating or cooling after the anneal, stress can build within the substrate 902 and help to separate the combination of the conductive film 908, the metal-containing film 906, the doped region 904, and a semiconductor layer 1010, which is a separated portion of the substrate 902, from a remaining portion of the substrate 902, as illustrated in FIG. 10. The resultant workpiece 1000 can be further processed to form a semiconductor device. In this particular embodiment, the semiconductor device can be in the form of a rectangular sheet, as opposed to a circular disk. In still another embodiment, the substrates may be substantially rectangular and be formed using an edge-defined growth technique.

By now it should be appreciated that there has been provided a method for the formation of semiconductor devices with metallic support on backside without the need for a separate substrate. The semiconductor device has been separated from a substrate by a process in which a differential etch layer is selectively removed.

The embodiments described herein allow a semiconductor device to be formed and separated more readily from a substrate. A mechanical operation may not need to be performed for the separation. Further, use of the differential etch layer can improve control and reproducibility of the thickness of the semiconductor layer from semiconductor device to semiconductor device. The differential etch layer can be removed by a variety of different techniques, including wet etching, dry etching, and electrochemistry. Still further, the resulting surfaces of the semiconductor layers may be smoother when using embodiments as described herein are used, as compared to a mechanical tearing operation. Thus, after reading this specification, skilled artisans will appreciate methods described herein can be used to form a semiconductor device with a metallic layer as a support on without the need for a separate substrate or handle to be used, such as during a mechanical tearing operation.

Many different aspects and embodiments are possible. Some of those aspects and embodiments are described below. After reading this specification, skilled artisans will appreciate that those aspects and embodiments are only illustrative and do not limit the scope of the present invention.

In a first aspect, a method can include forming a metallic layer by an electrochemical process over a workpiece. The workpiece can include a semiconductor substrate, a differential etch layer that is substantially lattice matched to the semiconductor substrate, and a semiconductor layer that is substantially lattice matched to the differential etch layer. The method can also include removing the differential etch layer to form a separated semiconductor layer.

In an embodiment of the first aspect, removing the differential etch layer includes removing the differential etch layer by a wet etch process. In another embodiment, the metallic layer is formed by physical vapor deposition, atomic layer deposition, chemical vapor deposition, or any combination thereof. In still another embodiment, the metallic layer includes titanium, tungsten, palladium, copper, tin, nickel, or any combination thereof. In yet another embodiment, forming the metallic layer further includes mechanically applying a metallic paste over the semiconductor substrate.

In a further embodiment of the first aspect, the semiconductor substrate includes silicon, germanium, gallium arsenide, gallium nitride, indium phosphide, or any combination thereof. In still a further embodiment, the differential etch layer includes germanium or a porous semiconductor material. In yet a further embodiment, the method further includes adding contacts to the separated semiconductor layer to form a photovoltaic cell. In another embodiment, the method further includes adding contacts to the separated semiconductor layer to form a light emitting device.

In a second aspect, a method can include forming a differential etch layer over a semiconductor substrate, forming a semiconductor layer over the differential etch layer, and forming a metallic layer by an electrochemical process over a workpiece. The method can also include removing the differential etch layer by an isotropic process and separating the semiconductor layer and the metallic layer from the semiconductor substrate.

In an embodiment of the second aspect, removing the differential etch layer includes removing the differential etch layer by a wet etch process. In another embodiment, the metallic layer is formed by physical vapor deposition, atomic layer deposition, chemical vapor deposition, an electrochemical process, or any combination thereof. In still another embodiment, the metallic layer includes titanium, tungsten, palladium, copper, tin, nickel, or any combination thereof. In yet another embodiment, forming the metallic layer further includes mechanically applying a metallic paste over the semiconductor substrate.

In a further embodiment of the second aspect, the semiconductor substrate includes silicon, germanium, gallium arsenide, gallium nitride, indium phosphide, or any combination thereof. In still a further embodiment, the differential etch layer includes germanium or a porous semiconductor material. In yet a further embodiment, the method further includes adding contacts to the separated semiconductor layer to form a photovoltaic cell. In another embodiment, the method further includes adding contacts to the separated semiconductor layer to form a light emitting device.

In a third aspect, a method of forming an electronic device can include forming a first metallic layer over a first side of a workpiece including a substrate, a first differential etch layer, and a first semiconductor layer. The first differential etch layer may lie between the substrate and the first semiconductor layer, and the first semiconductor layer may lie along the first side of the workpiece. The method can also include selectively removing at least a majority of the first differential etch layer from between the substrate and the first semiconductor layer, and separating the first semiconductor layer and the first metallic layer from the substrate.

In an embodiment of the third aspect, the substrate is a substantially monocrystalline semiconductor substrate. In another embodiment, the substrate includes a substantially monocrystalline region adjacent to the first side, and the first differential etch layer is substantially lattice matched to the surface region. In a particular embodiment, the first differential etch layer includes a different semiconductor element as compared to the first semiconductor layer. In still another embodiment, the first differential etch layer includes a different semiconductor element as compared to the substrate. In yet another embodiment, the first differential etch layer includes germanium, and the substrate is substantially free of germanium. In a further embodiment, the first semiconductor layer principally includes silicon, germanium, gallium arsenide, gallium nitride, indium phosphide, or any combination thereof. In still a further embodiment, the substrate and the first semiconductor layer include a same semiconductor element. In yet a further embodiment, the substrate principally includes silicon, the differential etch layer includes germanium, and the first semiconductor layer includes a Group 13-Group 15 semiconductor material. In still another embodiment, the differential etch layer includes a porous semiconductor material.

In another embodiment of the third aspect, the method further includes doping a portion of the first semiconductor layer with a dopant having a conductivity type opposite that of a remaining portion of the first semiconductor layer immediately adjacent to the doped portion. In still another embodiment, the method further includes depositing a doped semiconductor layer over first semiconductor layer before forming the first metallic layer, wherein the doped semiconductor layer has a conductivity type opposite that of the first semiconductor layer.

In another embodiment of the third aspect, the first metallic layer includes titanium, tungsten, palladium, copper, tin, nickel, copper, silver, gold, or any combination thereof. In still another embodiment, forming the first metallic layer further includes forming an adhesion film, a barrier film, or both over the first semiconductor layer. In yet another embodiment, forming the first metallic layer further includes forming a seed film over the first semiconductor layer. In a further embodiment, forming the first metallic layer further includes forming a conductive support film over the first semiconductor layer. In still a further embodiment, forming the first metallic layer is performed using an electrochemical process, physical vapor deposition, atomic layer deposition, chemical vapor deposition, or any combination thereof. In yet a further embodiment, forming the metallic layer further includes mechanically applying a metallic paste over the semiconductor.

In another embodiment of the third aspect, forming the first metallic layer such that a thickness of the first metallic layer is thicker than a thickness of the first semiconductor layer. In another embodiment, forming the first metallic layer such that a thickness of the first metallic layer is at least approximately 11 times thicker than a thickness of the first semiconductor layer. In still another embodiment, forming the first metallic layer is performed such that a thickness of the first metallic layer, by itself, provides sufficient mechanical support to the first semiconductor layer.

In a further embodiment of the third aspect, selectively removing the at least a majority of the first differential etch layer is performed using an isotropic etch. In a particular embodiment, selectively removing is performed using a wet etching technique. In a more particular embodiment, selectively removing is performed using an etching solution that dynamically moves within a container. In another particular embodiment, selectively removing is performed using a dry etching technique. In still a further embodiment, selectively removing the at least a majority of the first differential etch layer is performed using an electrochemical process. In a particular embodiment, forming the first metallic layer and selectively removing the at least a majority of the first differential etch layer are formed using a same bath. In yet a further embodiment, selectively removing the at least a majority of the first differential etch layer removes substantially all of the first differential etch layer lying between the first semiconductor layer and the substrate. In another embodiment, selectively removing the at least a majority of the first differential etch layer and separating the first semiconductor layer and the first metallic layer from the substrate occur substantially simultaneously during a particular time period.

In still another embodiment of the third aspect, separating the first semiconductor layer and the first metallic layer from the substrate includes mechanically separating the first semiconductor layer and the first metallic layer from the substrate. In a particular embodiment, mechanically separating the first semiconductor layer and the first metallic layer from the substrate is performed using a wedge, wire, a saw, or any combination thereof. In yet another embodiment, the method further includes adding contacts to the first semiconductor layer after separating the first semiconductor layer and the first metallic layer from the substrate. In a further embodiment, the electronic device includes a photovoltaic cell that includes the first semiconductor layer and the first metallic layer. In still a further embodiment, the electronic device includes a light emitting device that includes the first semiconductor layer and the first metallic layer. In yet a further embodiment, the electronic device includes a radiation detector that includes the first semiconductor layer and the first metallic layer.

In another embodiment of the first aspect, the method further includes forming a second metallic layer over a second side of the workpiece further includes a second differential etch layer and a second semiconductor layer, wherein the second side is opposite the first side, the second differential etch layer lies between the substrate and the second semiconductor layer, and the second semiconductor layer lies along the second side of the workpiece. The method further includes selectively removing at least a majority of the second differential etch layer from between the substrate and the second semiconductor layer, and separating a second semiconductor layer and the second metallic layer from the substrate.

In a particular embodiment, forming the first metallic layer and forming a second metallic layer are performed substantially simultaneously during a first time period, and selectively removing at least a majority of the first differential etch layer and selectively removing at least a majority of the second differential etch layer are performed substantially simultaneously during a second time period. In another particular embodiment, a combination of the first semiconductor layer and first metallic layer is of a first semiconductor device type, a combination of the second semiconductor layer and second metallic layer is of the first semiconductor device type, and a thickness of the first semiconductor layer is substantially the same as a thickness of the second semiconductor layer. In still another particular embodiment, a combination of the first semiconductor layer and first metallic layer is of a first semiconductor device type, a combination of the second semiconductor layer and second metallic layer is of a second semiconductor device type, and a thickness of the first semiconductor layer is different from a thickness of the second semiconductor layer.

Note that not all of the activities described above in the general description or the examples are required, that a portion of a specific activity may not be required, and that one or more further activities may be performed in addition to those described. Still further, the order in which activities are listed is not necessarily the order in which they are performed.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

1. A method comprising:
forming a metallic layer by an electrochemical process over a workpiece, wherein the workpiece comprises a semiconductor substrate, a differential etch layer that is substantially lattice matched to the semiconductor substrate, and a semiconductor layer that is substantially lattice matched to the differential etch layer; and
removing the differential etch layer to form a separated semiconductor layer.

2. The method of claim 1, wherein removing the differential etch layer comprises removing the differential etch layer by a wet etch process.

3. The method of claim 1, wherein the metallic layer is formed by physical vapor deposition, atomic layer deposition, chemical vapor deposition, or any combination thereof.

4. The method of claim 1, wherein the metallic layer comprises titanium, tungsten, palladium, copper, tin, nickel, or any combination thereof.

5. The method of claim 1, wherein forming the metallic layer further comprises mechanically applying a metallic paste over the semiconductor substrate.

6. The method of claim 1, wherein the semiconductor substrate comprises gallium arsenide.

7. The method of claim 1, wherein the semiconductor substrate comprises silicon, germanium, gallium arsenide, gallium nitride, indium phosphide, or any combination thereof.

8 The method of claim 1, wherein the differential etch layer comprises germanium

9. The method of claim 1, wherein the differential etch layer comprises a porous semiconductor material.

10. The method of claim 1, further comprising adding contacts to the separated semiconductor layer to form a photovoltaic cell.

11. The method of claim 1, further comprising adding contacts to the separated semiconductor layer to form a light emitting device.

12. A method comprising:
forming a differential etch layer over a semiconductor substrate;
forming a semiconductor layer over the differential etch layer;
forming a metallic layer by an electrochemical process over a workpiece;
removing the differential etch layer by an isotropic process; and
separating the semiconductor layer and the metallic layer from the semiconductor substrate.

13. The method of claim 12, wherein removing the differential etch layer comprises removing the differential etch layer by a wet etch process.

14. The method of claim 12, wherein the metallic layer is formed by physical vapor deposition, atomic layer deposition, chemical vapor deposition, an electrochemical process, or any combination thereof.

15. The method of claim 12, wherein the metallic layer comprises titanium, tungsten, palladium, copper, tin, nickel, or any combination thereof.

16. The method of claim 12, wherein forming the metallic layer further comprises mechanically applying a metallic paste over the semiconductor substrate.

17. The method of claim 12, wherein the semiconductor substrate comprises gallium arsenide.

18. The method of claim 12, wherein the semiconductor substrate comprises silicon, germanium, gallium arsenide, gallium nitride, indium phosphide, or any combination thereof.

19. The method of claim 12, wherein the differential etch layer comprises germanium.

20. The method of claim 12, wherein the differential etch layer comprises a porous semiconductor material.

21. The method of claim 12, further comprising adding contacts to the separated semiconductor layer to form a photovoltaic cell.

22. The method of claim 12, further comprising adding contacts to the separated semiconductor layer to form a light emitting device.

23-78. (canceled)
